(19) United States
(12) Patent Application Publication
(10) Pub. No.: US 2026/0182179 A1
(43) Pub. Date: Jun. 25, 2026

(54) DISPLAY DEVICE AND METHOD FOR FABRICATING THE SAME

(71) Applicant: Samsung Display Co., LTD., Yongin-si (KR)

(72) Inventors: Kyung Bin CHOI, Yongin-si (KR); Seung Jae KANG, Yongin-si (KR); Ki Yong KIM, Yongin-si (KR); Eun Byul KIM, Yongin-si (KR); Hee Ju WOO, Yongin-si (KR)

(21) Appl. No.: 19/273,895

(22) Filed: Jul. 18, 2025

(30) Foreign Application Priority Data
Dec. 24, 2024 (KR) 10-2024-0195364

(51) Int. Cl. H10K 59/131; H10K 59/12

(52) U.S. Cl. CPC H10K 59/131; H10K 59/1201

(57) ABSTRACT

A display device includes: a display panel; a pad arranged in a non-display area of a substrate of the display panel; a driver circuit including a terminal arranged on the pad; and a bonding layer arranged between the display panel and the driver circuit in the non-display area. The bonding layer includes: a first viscous layer overlapping the terminal in a thickness direction of the display panel; and a second viscous layer arranged on the display panel not to overlap the terminal in the thickness direction of the display panel. A viscosity of the first viscous layer is different from a viscosity of the second viscous layer.

This application claims priority to Korean Patent Application No. 10-2024-0195364, filed on Dec. 24, 2024, and all the benefits accruing therefrom under 35 U.S.C. § 119, the content of which in its entirety is herein incorporated by reference.

### BACKGROUND

### 1. Field

The present disclosure relates to a display device, and more particularly, to a display device in which a pad of a display panel and a terminal of a driver circuit can be reliably in contact with each other, and bubbles between the display panel and the driver circuit can be suppressed, an electronic device including the same, and a method for fabricating a display device.

### 2. Description of the Related Art

An organic light-emitting diode display, unlike a liquid-crystal display, is self-luminous. Accordingly, an organic light-emitting diode display may not include a separate light source and thus the organic light-emitting diode display can be made lighter and thinner. In addition, an organic light-emitting diode display has high-quality characteristics such as low power consumption, high luminance and fast response speed, and thus is attracting attention as the next generation display.

### SUMMARY

Aspects of the present disclosure provide a display device in which a pad of a display panel and a terminal of a driver circuit can be reliably in contact with each other, and bubbles between the display panel and the driver circuit can be suppressed, an electronic device including the display device, and a method for fabricating a display device.

According to an embodiment of the present disclosure, there is provided a display device including: a display panel; a pad arranged in a non-display area of a substrate of the display panel; a driver circuit including a terminal arranged on the pad; and a bonding layer arranged between the display panel and the driver circuit in the non-display area. In such an embodiment, the bonding layer includes: a first viscous layer overlapping with the terminal in a thickness direction of the display panel; and a second viscous layer arranged on the display panel not to overlap the terminal in the thickness direction of the display panel. In such an embodiment, a viscosity of the first viscous layer is different from a viscosity of the second viscous layer.

According to another embodiment of the present disclosure, there is provided an electronic device including: a display device which provides a screen. In such an embodiment, the display device includes: a display panel; a pad arranged in a non-display area of a substrate of the display panel; a driver circuit including a terminal arranged on the pad; and a bonding layer arranged between the display panel and the driver circuit in the non-display area. In such an embodiment, the bonding layer includes: a first viscous layer overlapping the terminal in a thickness direction of the display panel; and a second viscous layer arranged on the display panel not to overlap the terminal in the thickness direction of the display panel. In such an embodiment, a viscosity of the first viscous layer is different from a viscosity of the second viscous layer.

According to yet another embodiment of the present disclosure, there is provided a method for fabricating a display device. In such an embodiment, the method includes:
preparing a display panel including a pad in a non-display area of a substrate; forming a bonding layer on the pad; placing a mask above the bonding layer in a way such that a semi-transparent region of the mask overlaps the pad and a transparent region of the mask does not overlap the pad; irradiating the bonding layer with ultraviolet ray through the mask to form the bonding layer in in which a first viscous layer in overlapping the semi-transparent region and a second viscous layer overlapping the transparent region have different viscosities from each other; arranging a driver circuit on the bonding layer to overlap a terminal of the driver circuit with the first viscous layer of the bonding layer; and lowering the driver circuit toward the bonding layer to bring the terminal of the driver circuit into contact with the pad.

According to an embodiment of the present disclosure, a pad of a display panel and a terminal of a driver circuit in a display device can be reliably in contact with each other, and bubbles between the display panel and the driver circuit can be suppressed.

For example, according to an embodiment of the present disclosure, a bonding layer having different viscosities may be located between pads of the display panel and terminals of the driver circuit. Accordingly, as the bonding layer with relatively low viscosity between a pad and a terminal spreads out to the periphery, the pad and the terminal can be closely attached to each other so that the contact force between the pad and the terminal can be enhanced. In addition, as the bonding layer (the bonding layer with low viscosity) spreads out to the periphery, it is located between the display panel and the driver circuit by the bonding layer with relatively high viscosity to fill between them, it is possible to suppress bubbles between the display panel and the driver circuit.

The effects of the present disclosure are not limited to the above-described effects and other effects which are not described herein will become apparent to those skilled in the art from the following description.

### BRIEF DESCRIPTION OF THE DRAWINGS

The above and other features of embodiments of the present disclosure will become more apparent by describing in detail embodiments thereof with reference to the attached drawings, in which:

FIG. 1 is a plan view showing a display device according to an embodiment of the present disclosure.

FIG. 2 is a plan view of the display device of FIG. 1 from which a driver circuit, a first circuit board, and a second circuit board have been removed.

FIG. 3 is an enlarged view of area A1 of FIG. 2.

FIG. 4 is a cross-sectional view taken along line I-I′ of FIG. 3.

FIG. 5 is a view for illustrating an example of a bonding layer arranged on the pads of FIG. 3.

FIG. 6 is a view for illustrating an example of a bonding layer arranged on the pads of FIG. 3.

FIGS. 7, 8, 9, 10, 11, 12 and 13 are cross-sectional views for illustrating a method for fabricating a display device according to an embodiment of the present disclosure.

FIG. 14 is a plan view of a bonding layer according to an embodiment of the present disclosure.

FIG. 15 is a block diagram of an electronic device according to an embodiment of the present disclosure.

FIGS. 16, 17 and 18 are views showing electronic devices according to a variety of embodiments of the present disclosure.

### DETAILED DESCRIPTION

The invention will now be described more fully hereinafter with reference to the accompanying drawings, in which various embodiments of the invention are shown. This invention may, however, be embodied in different forms and should not be construed as limited to the embodiments set forth herein. Rather, these embodiments are provided so that this disclosure will be thorough and complete, and will fully convey the scope of the invention to those skilled in the art. Like reference numerals refer to like elements throughout.

It will also be understood that when a layer is referred to as being “on” another layer or substrate, it can be directly on the other layer or substrate, or intervening layers may also be present therebetween. In contrast, when an element is referred to as being “directly on” another element, there are no intervening elements present.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. Thus, reference to “an” element in a claim followed by reference to “the” element is inclusive of one element and a plurality of the elements. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10% or 5% of the stated value.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

Hereinafter, embodiments will be described with reference to the accompanying drawings.

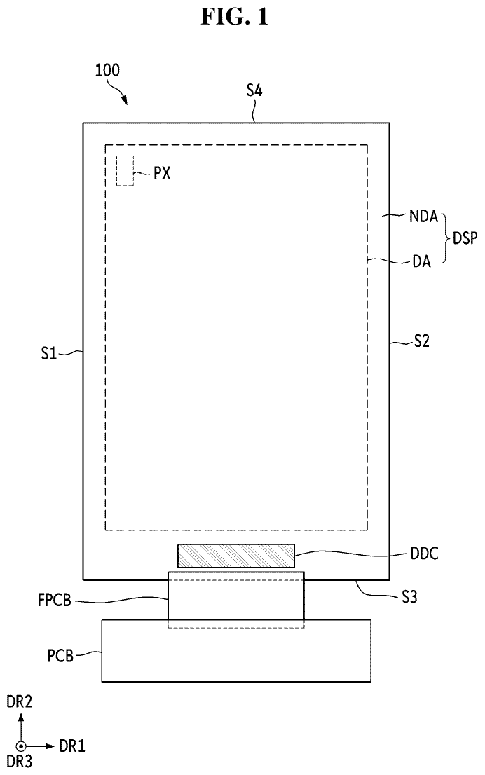

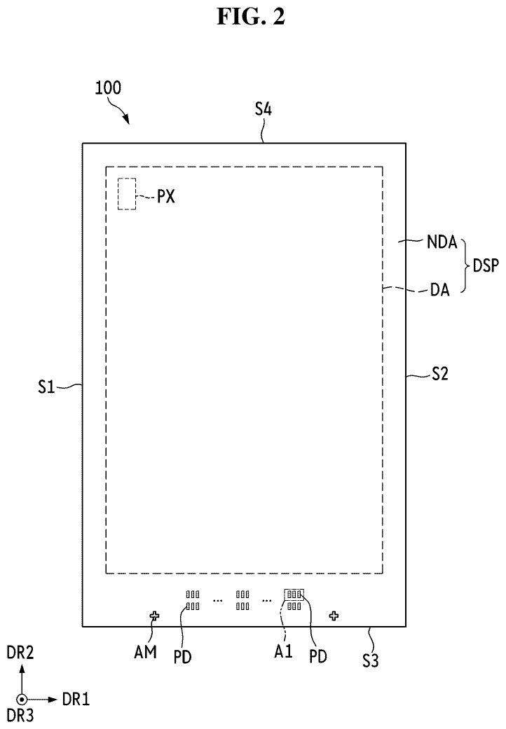

FIG. 1 is a plan view showing a display device 100 according to an embodiment of the present disclosure. FIG. 2 is a plan view of the display device of FIG. 1 from which a driver circuit, a first circuit board, and a second circuit board have been removed.

Referring to FIG. 1, an embodiment of a display device 100 is for displaying moving images or still images. The display device 1 may be used as the display screen of portable electronic devices such as a mobile phone, a smart phone, a tablet personal computer (PC), a smart watch, a watch phone, a mobile communications terminal, an electronic notebook, an electronic book, a portable multimedia player (PMP), a navigation device and a ultra mobile PC (UMPC), as well as the display screen of various products such as a television, a notebook, a monitor, a billboard and the Internet of Things. Those listed-above are merely examples, and the display device 100 may be employed in other electronic devices as well.

In an embodiment, the display device 100 may be a light-emitting display device such as an organic light-emitting display device including organic light-emitting diodes, a quantum-dot light-emitting display device including quantum-dot light-emitting layer, and an ultra-small light-emitting display device including ultra-small light-emitting diodes such as micro or nano light-emitting diodes (micro LEDs or nano LEDs). It should be understood, however, that the present disclosure is not limited thereto. In another embodiment, for example, the display device 100 may be other types of display devices than light-emitting display devices. In the following descriptions, for convenience of description, embodiments where the display device 100 is a light-emitting display device (e.g., an organic light-emitting display device) will be mainly described.

In an embodiment, the display device 100 may include a display panel DSP, a first circuit board FPCB, a second circuit board PCB, and a driver circuit DDC (e.g., a data driver circuit).

The display panel DSP may be a rigid display panel that is not substantially deformed, or a flexible display panel that can be deformed, i.e., at least partially folded, bent or rolled. The display panel DSP may be provided to the display device 100 without being bent or with being partially bent.

The display panel DSP 200 may include a display area DA and a non-display area NDA.

A plurality of pixels PX may be arranged in the display area DA. The pixels PX can display images. In addition, a plurality of gate lines and a plurality of emission lines connected to the pixels PX may be arranged in the display area DA. The display area DA may have a variety of shapes depending on embodiments. In an embodiment, for example, the display area DA may have a rectangular shape, a non-rectangular polygonal shape, a circular shape, an elliptical shape, an irregular shape, or other shapes in a plan view. According to an embodiment of the present disclosure, the display area DA may have a shape that conforms to the shape of the display panel DSP.

The non-display area NDA may be located around the display area DA. According to the embodiment of the present disclosure, the non-display area NDA may surround the display area DA. A gate driver and an emission driver for driving the pixels PX may be arranged in the non-display area NDA of the display panel DSP. The gate driver may be connected to the gate lines, and the emission driver may be connected to the emission lines. The gate signals from the gate driver may be provided to the pixels PX through the gate lines, and emission signals from the emission driver may be provided to the pixels PX through the emission lines.

A first side S1 and a second side S2 of the display panel DSP face each other in a first direction DR1, and a third side S3 and a fourth side S4 of the display panel DSP may face each other in a second direction DR2 crossing the first direction DR1. The first circuit board FPCB described above may overlap the third side S3 in a third direction DR3, which is perpendicular to the first direction DR1 and the second direction DR2. Here, the third direction may be a thickness direction of the display panel DSP. The first side S1 or the second side S2 may be longer than the third side S3 or the fourth side S4. It should be understood, however, that the embodiments of the present disclosure are not limited thereto. The lengths of the first side S1, the second side S2, the third side S3 and the fourth side S4 may be changed in a variety of ways.

The driver circuit DDC may be connected to the display panel DSP. In an embodiment, for example, the driver circuit DDC may be electrically connected to the non-display area NDA of the display panel DSP. The driver circuit DDC may include or be defined by, for example, an integrated circuit.

The first circuit board FPCB may be connected to the display panel DSP and the second circuit board PCB. In an embodiment, for example, one side of the first circuit board FPCB may be electrically connected to the non-display area NDA of the display panel DSP, and the other side of the first circuit board FPCB may be electrically connected to the second circuit board PCB. The first circuit board FPCB may be, but is not limited to, a flexible film such as a flexible printed circuit board and a printed circuit board. In an embodiment, for example, the first circuit board FPCB may be a flexible printed circuit board.

The second circuit board PCB may be electrically connected to the display panel DSP through the first circuit board FPCB and may send/receive signals to/from the driver circuit DDC. The second circuit board PCB may provide image data, a control signal, supply voltage, etc. to the display panel DSP or the first circuit board FPCB. Active components and passive components may be arranged on the second circuit board PCB. In an embodiment, for example, a timing controller and a power supply unit may be arranged on the second circuit board PCB. The second circuit board PCB may be, but is not limited to, a flexible printed circuit board or a printed circuit board. In an embodiment, for example, the second circuit board PCB may be a rigid printed circuit board.

The power supply unit may apply supply voltages to the pixels PX, the gate driver, the emission driver, and the data driver circuit DDC. The timing controller may control the operations of the gate driver, the emission driver ED, and the driver circuit DDC.

A gate timing control signal, an emission timing control signal, a gate clock signal, an emission clock signal, a gate start signal, an emission start signal, a high-level voltage and a low-level voltage from the timing controller arranged on the second circuit board PCB may be provided to the first gate driver and the emission driver through the first circuit board FPCB. In an embodiment, for example, the gate timing control signal, the gate clock signal, the gate start signal, the high-level voltage and the low-level voltage may be provided to the gate driver, and the emission timing control signal, the emission clock signal, the emission start signal, the high-level voltage and the low-level voltage may be provided to the emission driver. In addition, power signals from the power supply unit arranged on the second circuit board may be provided to the gate driver, the emission driver and the pixels PX through the first circuit board. The power signals may include, for example, a supply voltage, a common voltage, an initialization voltage, and a bias voltage.

In an embodiment, as shown in FIG. 2, a plurality of pads PD may be arranged in the non-display area NDA of the display panel DSP. In an embodiment, for example, a plurality of pads PD may be arranged close to one edge (e.g., the third side S3) of the display panel DSP. The plurality of pads PD may be arranged along the third side S3. In an embodiment, for example, the plurality of pads PD may be arranged in the first direction DR1.

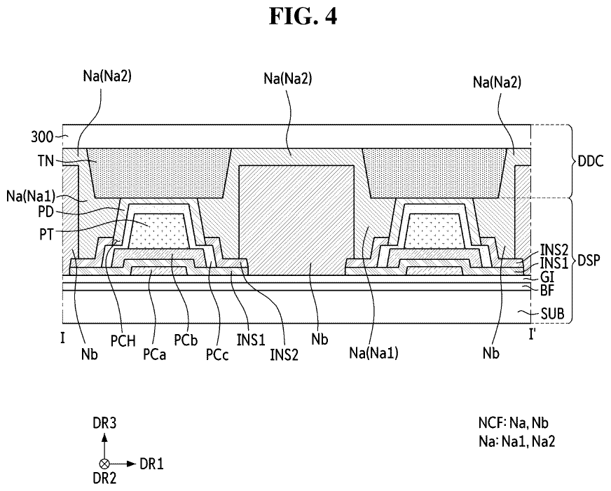

The plurality of pads PD of the display panel DSP may be connected to a plurality of terminals TN (see FIG. 4) or bumps of the driver circuit DDC. Among the plurality of pads PD of FIG. 2, pads closer to the third side S3 (e.g., input pads) may transmit signals from the first circuit board FPCB and the second circuit board PCB to the driver circuit DDC. Among the plurality of pads PD of FIG. 2, pads closer to the display area DA (e.g., output pads) may transmit signals from the driver circuit DDC to the pixels PX of the display area DA.

Alignment marks AM may be further arranged on opposite sides of the pads PD of the display panel DSP. The alignment marks AM may be used to align the display panel DSP with the driver circuit DDC.

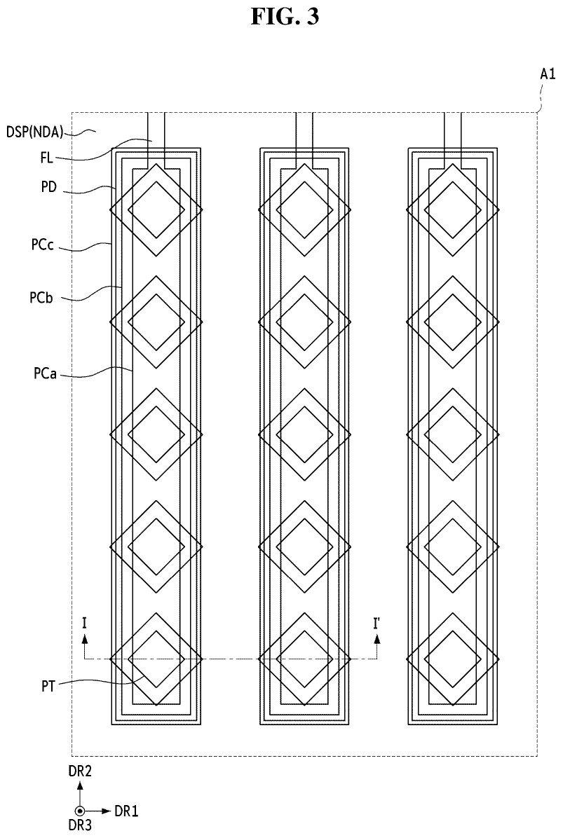

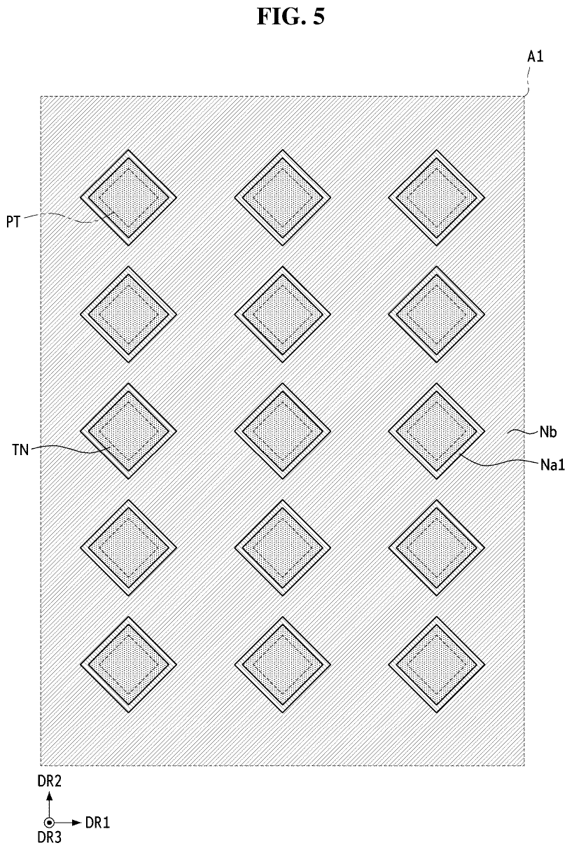

FIG. 3 is an enlarged view of area A1 of FIG. 2. FIG. 4 is a cross-sectional view taken along line I-I′ of FIG. 3. FIG. 5 is a view for illustrating an example of a bonding layer NCF arranged on the pads of FIG. 3.

In an embodiment, as shown in FIG. 4, a buffer layer BF may be arranged on a substrate SUB of the display panel DSP, and a gate insulator GI may be arranged on the buffer layer BF.

A first pad connection electrode PCa may be arranged on the gate insulator GI. In an embodiment, for example, the first pad connection electrode PCa may be located on the gate insulator GI in the non-display area NDA of the substrate SUB. The first pad connection electrode PCa may include a conductive material including molybdenum (Mo), aluminum (Al), copper (Cu), titanium (Ti), etc., and may be made up of (or defined by) multiple layers or a single layer including at least one selected from the above-listed materials. A first insulating layer INS1 may be located on the first pad connection electrode PCa.

A first insulating layer INS1 may be located on the first pad connection electrode PCa.

A second pad connection electrode PCb may be located on the first insulating layer INS1 such that it overlaps with the first pad connection electrode PCa. In an embodiment, for example, the second pad connection electrode PCb may be located on the first insulating layer INS1 to overlap the first pad connection electrode PCa in the non-display area NDA of the substrate SUB. The second pad connection electrode PCb may be connected to the first pad connection electrode PCa. To this end, a portion of the second pad connection electrode PCb extended toward the display area DA may be connected to a fan-out line FL through a contact hole penetrating (or defined through) the first insulating layer INS1. The fan-out line FL may be formed integrally with the first pad connection electrode PCa as a single unitary indivisible part. The second pad connection electrode PCb may include aluminum (Al), platinum (Pt), palladium (Pd), silver (Ag), magnesium (Mg), gold (Au), nickel (Ni), neodymium (Nd), iridium (Ir), chromium (Cr), calcium (Ca), molybdenum (Mo), titanium (Ti), tungsten (W) and/or copper (Cu), and may be made up of a single layer or multiple layers including at least one selected from the above-listed materials.

Protruding patterns PT may be arranged on the second pad connection electrode PCb. In an embodiment, for example, the protruding patterns PT may be arranged on the second pad connection electrode PCb in a pad contact hole PCH of the second insulating layer INS2. The protruding patterns PT may be in contact (or direct contact) with the second pad connection electrode PCb. In the plan view of FIG. 3, the protruding patterns PT may have a rectangular shape (e.g., a diamond shape). In the cross-sectional view of FIG. 4, the protruding patterns PT may have a trapezoidal shape. It should be understood, however, that the embodiments of the present disclosure are not limited thereto. The protruding patterns PT may have a variety of planar shapes such as a circle and a triangle. The protruding patterns PT may include a polymer-based material. The polymer-based material may include at least one selected from an acrylic resin, an epoxy resin, polyimide, polyethylene, etc.

The third pad connection electrode PCc may be located on the protruding patterns PT, the second pad connection electrode PCb, and the first insulating layer INS1. For example, the third pad connection electrode PCc may be located on the protruding patterns PT, the second pad connection electrode PCb, and the first insulating layer INS1 in the non-display area NDA of the substrate SUB. The third pad connection electrode PCc may be in contact (or direct contact) with each of the protruding patterns PT, the second pad connection electrode PCb and the first insulating layer INS1. The third pad connection electrode PCc may be connected to the first pad connection electrode PCa through the second pad connection electrode PCb. The third pad connection electrode PCc may include aluminum (Al), platinum (Pt), palladium (Pd), silver (Ag), magnesium (Mg), gold (Au), nickel (Ni), neodymium (Nd), iridium (Ir), chromium (Cr), calcium (Ca), molybdenum (Mo), titanium (Ti), tungsten (W) and/or copper (Cu), and may be made up of a single layer or multiple layers including at least one selected from the above-listed materials.

The second insulating layer INS2 may be located on the third pad connection electrode PCc.

A pad PD may be located on the third pad connection electrode PCc. In an embodiment, for example, the pad PD may be located on the third pad connection electrode PCc in the non-display area NDA of the substrate SUB. The pad PD may be located on the third pad connection electrode PCc to overlap a plurality of protrusion patterns PT. The pad PD may be in contact (or direct contact) with the third pad connection electrode PCc. In an embodiment, for example, the pad PD may be in contact (or directly contact) with the third pad connection electrode PCc through the pad contact hole PCH penetrating (or defined through) the second insulating layer INS2. The pad PD may be connected to a fan-out line FL. In an embodiment, for example, the pad PD may be connected to the fan-out line FL via the third pad connection electrode PCc, the second pad connection electrode PCb and the first pad connection electrode PCa. The fan-out line FL may be connected to, e.g., a data line. The pad PD may include a conductive material including molybdenum (Mo), aluminum (Al), copper (Cu), titanium (Ti), etc., and may be made up of multiple layers or a single layer including at least one selected from the above-listed materials. In an embodiment, for example, the pad PD may have a multilayer structure consisting of (or defined by) a first pad electrode containing titanium (Ti), a second pad electrode containing aluminum (Al), and a third pad electrode containing titanium (Ti). The second pad electrode may be located between the first pad electrode and the third pad electrode.

As a plurality of protruding patterns PT is arranged along the longitudinal direction of the pad PD (e.g., the second direction DR2), the pad PD on the plurality of protruding patterns PT may have concavities (concave portions) and convexities (convex portions). In an embodiment, for example, the pad PD may have convexities protruding in the third direction DR3 and concavities recessed in the opposite direction of the third direction DR3 (hereinafter, the third opposite direction). In an embodiment, for example, the pad PD may protrude in the third direction DR3 on the protruding pattern PT and may be recessed in the third opposite direction between adjacent protruding patterns PT. The pad PD protruding in the third direction DR3 may be in contact (or direct contact) with the terminal TN of the driver circuit DDC. By such contact, the pad PD of the display panel DSP may be electrically connected with the terminal TN of the driver circuit DDC.

In an embodiment, as shown in FIG. 4, the driver circuit DDC may be located on the pad PD of the display panel DSP.

The driver circuit DDC may include a substrate 300 and a terminal TN. The terminal TN may include or be made of a material including gold Au. The terminal TN of the driver circuit DDC may be connected to the pad PD of the display panel DSP. In an embodiment, for example, the terminal TN of the driver circuit DDC may be in contact (or direct contact) with the pad PD of the display panel DSP.

A plurality of transistors (or chips) may be arranged between the substrate 300 of the driver circuit DDC and the terminals TN. The substrate 300 may include, e.g., a wafer.

A bonding layer NCF may be arranged between the display panel DSP and the driver circuit DDC. In an embodiment, for example, the bonding layer NCF may be arranged between the pad PD and the terminal TN. The display panel DSP and the driver circuit DDC may be bonded to each other by the bonding layer NCF. The bonding layer NCF may include a non-conductive film. In an embodiment, for example, the bonding layer NCF may include or be made of a material including a resin.

The bonding layer NCF may include a first viscous layer Na and a second viscous layer Nb having different viscosities from each other. In an embodiment, for example, the viscosity of the first viscous layer Na may be less than the viscosity of the second viscous layer Nb. In addition, the first viscous layer Na and the second viscous layer Nb may have different transparencies from each other. In an embodiment, for example, the transparency of the first viscous layer Na may be greater than the transparency of the second viscous layer Nb.

The first viscous layer Na may overlap the terminal TN in the third direction DR3, which is a thickness direction of the substrate SUB. In an embodiment, for example, the first viscous layer Na may be arranged between the terminal TN of the driver circuit DDC and the second insulating layer INS2 of the display panel DSP. In addition, the first viscous layer Na may be further arranged between adjacent protruding patterns PT.

The first viscous layer Na may include a first subsidiary viscous layer Na1 and a second subsidiary viscous layer Na2 having a same viscosity as each other. The first subsidiary viscous layer Na1 may be arranged between the terminal TN of the driver circuit DDC and the second insulating layer INS2 of the display panel DSP. The second subsidiary viscous layer Na2 may be arranged between adjacent protruding patterns PT. The second subsidiary viscous layer Na2 may be arranged between the first viscous layer Na and the driver circuit DDC or the substrate SUB of the driver circuit DDC). The first subsidiary viscous layer Na1 and the second subsidiary viscous layer Na2 may be connected to each other and formed as a single body. Alternatively, the first subsidiary viscous layer Na1 and the second subsidiary viscous layer Na2 may not be connected with each other but may be separated from each other. In an embodiment, for example, the first viscous layer Na may include the first subsidiary viscous layer Na1 and the second subsidiary viscous layer Na2 separated from each other.

The second viscous layer Nb may be arranged between the display panel DSP and the driver circuit DDC not to overlap the protruding pattern PT or the terminal TN in the third direction DR3. In an embodiment, for example, the second viscous layer Nb may be arranged between the substrate SUB or the gate insulator GI of the display panel DSP and the substrate 300 of the driver circuit DDC not to overlap the protruding pattern PT or the terminal TN in the third direction DR3. The second viscous layer Nb may be arranged between adjacent first subsidiary viscous layers Na1. In addition, the second viscous layer Nb may be arranged between the gate insulator GI of the display panel DSP and the second subsidiary viscous layer Na2 between the adjacent first subsidiary viscous layers Na1. In addition, the second viscous layer Nb may be arranged between the second insulating layer INS2 of the display panel DSP and the second subsidiary viscous layer Na2 between the adjacent first subsidiary viscous layers Na1.

In the plan view of FIG. 5, the first subsidiary viscous layer Na1 may have a closed curve shape surrounding the protruding pattern PT and the terminal TN. In an embodiment, for example, the plurality of first subsidiary viscous layers Na1 may have a closed curve shape that surrounds each of the plurality of terminals TN (or the plurality of protrusion patterns PT). The first subsidiary viscous layer Na1 may have a same planar shape as the terminal TN when viewed from the top.

The second viscous layer Nb may be arranged between the first subsidiary viscous layers Na1.

According to an embodiment of the present disclosure, the bonding layer NCF may include a dye of a particular color. In such an embodiment, the first viscous layer Na and the second viscous layer Nb may represent different colors due to the difference in transparency between the first viscous layer Na and the second viscous layer Nb. In an embodiment, for example, the second viscous layer Nb may represent a darker color than the first viscous layer Na.

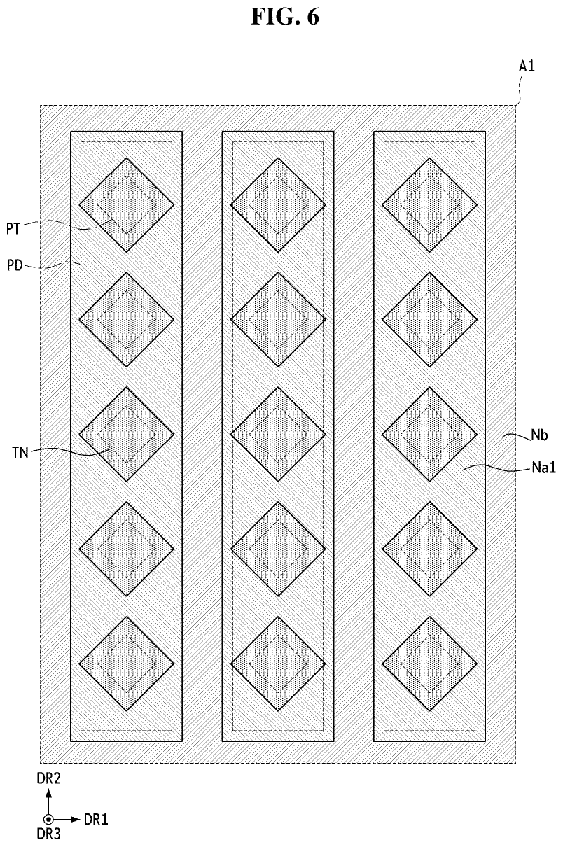

FIG. 6 is a view for illustrating an example of the bonding layer NCF arranged on the pads PD of FIG. 3.

In the plan view of FIG. 6, the border of the first subsidiary viscous layer Na1 may surround the pad PD.

The second viscous layer Nb may be arranged between the first subsidiary viscous layers Na1.

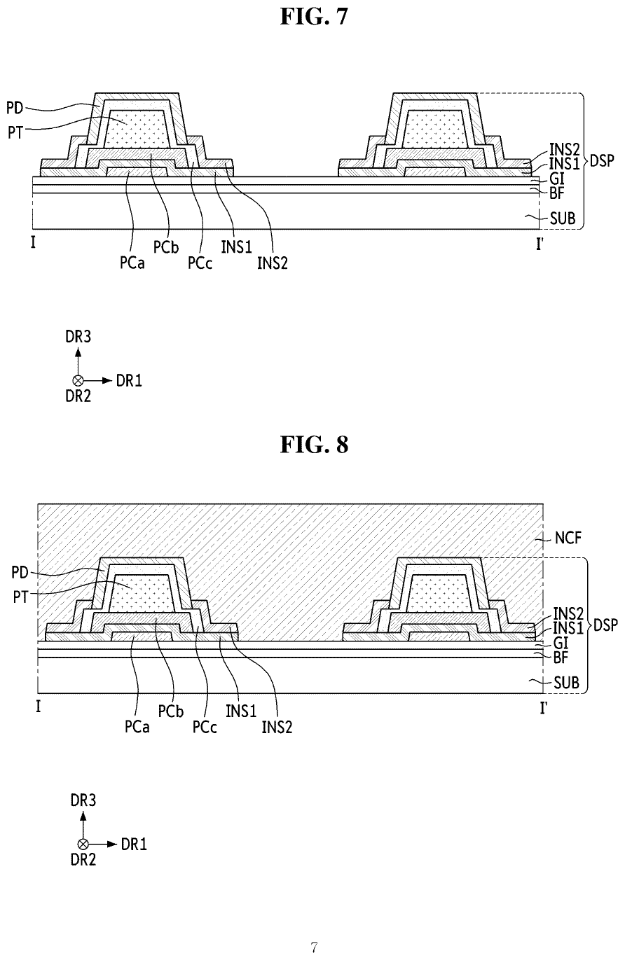

FIGS. 7, 8, 9, 10, 11, 12 and 13 are cross-sectional views for illustrating a method for fabricating a display device 100 according to an embodiment of the present disclosure. For example, FIGS. 7 to 12 may be cross-sectional views for illustrating processes of a method for fabricating the display device 100 of FIG. 4 described above.

Initially, as shown in FIG. 7, a display panel DSP may be prepared. The display panel DSP may include a substrate SUB, a buffer layer BF, a gate insulator GI, a first insulating layer INS1, a second insulating layer INS2, a first pad connection electrode PCa, a second pad connection electrode PCb, a third pad connection electrode PCc, a protruding pattern PT, and a pad PD.

Subsequently, a bonding layer NCF may be formed over (or to cover) the display panel DSP as shown in FIG. 8. In an embodiment, for example, by applying a resin, which is a raw material for the bonding layer NCF, on the pads PD, the second insulating layer INS2 and the gate insulator GI, the bonding layer NCF can be formed over the pads PD, the second insulating layer INS2 and the gate insulator GI.

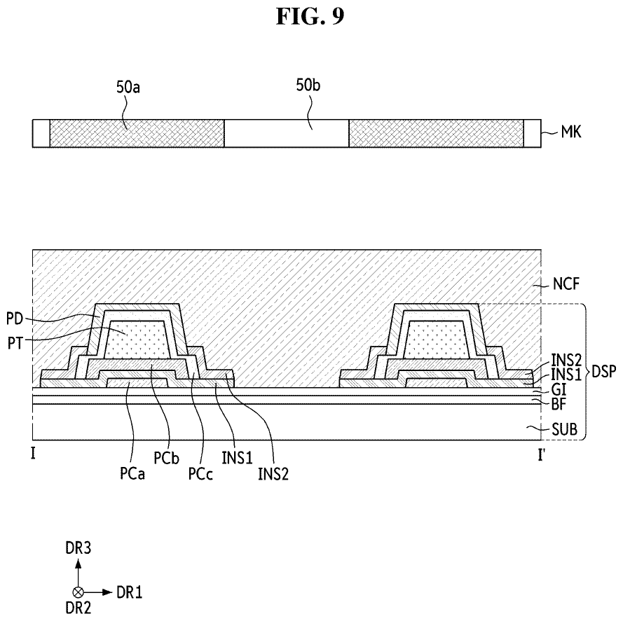

Subsequently, as shown in FIG. 9, a mask MK may be placed above the bonding layer NCF formed over the display panel DSP. The mask MK may include a plurality of semi-transparent regions 50a and a transparent region 50b. The transparent region 50b may transmit a larger amount of light (e.g., ultraviolet light) than the semi-transparent regions 50a. The mask MK may be placed above the bonding layer NCF so that the semi-transparent regions 50a are in line with (or overlap) the protruding patterns PT and the transparent region 50b is in line with (or overlap) the gate insulator GI and the second insulating layer INS2.

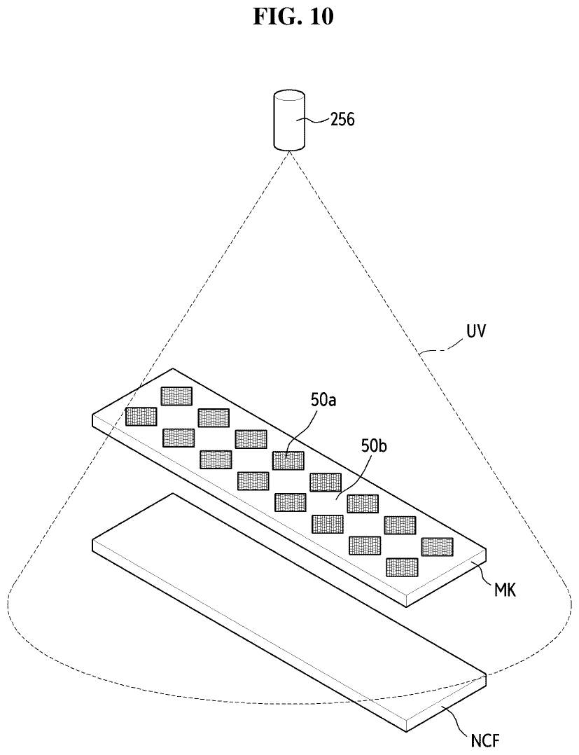

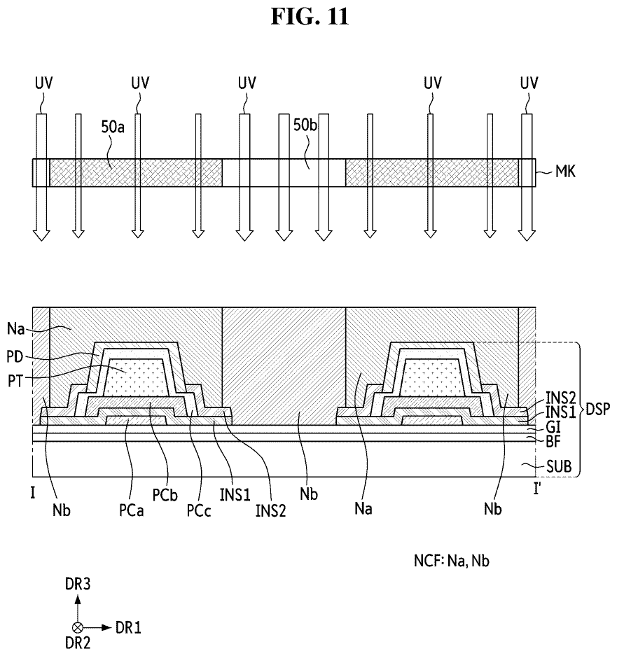

Subsequently, as shown in FIGS. 10 and 11, ultraviolet ray UV may be irradiated onto the mask MK from a light source 256. Ultraviolet ray UV from the light source 256 may be radiated onto the bonding layer NCF through the semi-transparent regions 50a and the transparent region 50b of the mask MK. The bonding layer NCF may be relatively weakly cured by ultraviolet ray UV radiated through the semi-transparent regions 50a of the mask MK, and may be relatively strongly cured by ultraviolet ray UV irradiated through the transparent region 50b of the mask MK. In other words, the bonding layer NCF may be cured more strongly under the transparent region 50b than under the semi-transparent regions 50a. Accordingly, the bonding layer NCF may be cured (e.g., pre-cured) to have a first viscous layer Na and a second viscous layer Nb having different viscosities from each other. The first viscous layer Na may overlap the protrusion pattern PT and the pad PD in the third direction DR3, and the second viscous layer Nb may be arranged between the first viscous layers Na in a plan view or when viewed in the third direction DR3. The viscosity of the first viscous layer Na may be less than the viscosity of the second viscous layer Nb. In addition, due to such a difference in the amount of ultraviolet ray UV, the first viscous layer Na and the second viscous layer Nb may have different transparencies from each other. In an embodiment, for example, the transparency of the first viscous layer Na may be greater than the transparency of the second viscous layer Nb.

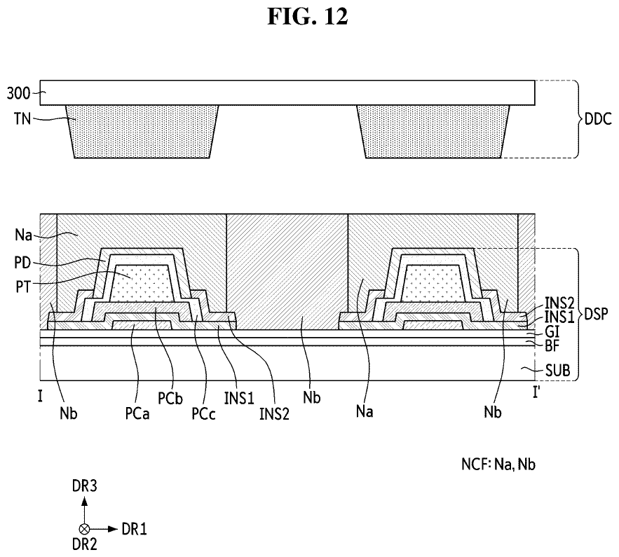

Subsequently, after the mask MK has been removed, as shown in FIG. 12, the driver circuit DDC including a terminal TN and a substrate 300 may be arranged on the bonding layer NCF including the first viscous layer Na and the second viscous layer Nb. In this process, the terminal TN of the driver circuit DDC may be arranged on the bonding layer NCF to overlaps the pad PD of the display panel DSP and the first viscous layer Na of the bonding layer NCF in the third direction DR3.

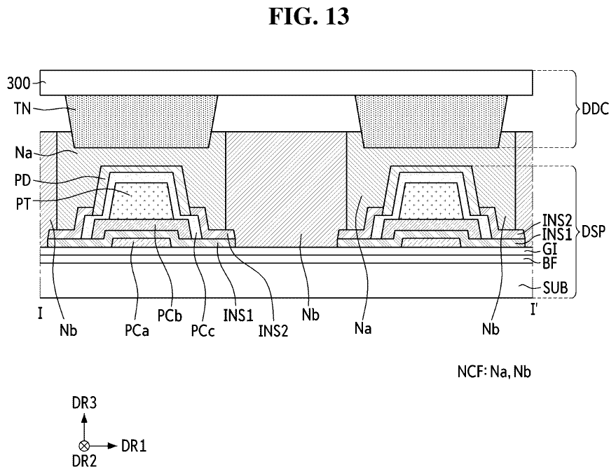

Subsequently, as shown in FIG. 13, the driver circuit DDC may be lowered toward the bonding layer NCF. In an embodiment, for example, the driver circuit DDC may be lowered (e.g., pressed) in the opposite direction of the third direction DR3 (hereinafter referred to as the third opposite direction). Then, the terminal TN of the driver circuit DDC may be brought into contact with the first viscous layer Na. In this process, since the viscosity of the first viscous layer Na is small, the portion of the first viscous layer Na in contact with the terminal TN of the driver circuit DDC may be depressed.

Subsequently, as shown in FIG. 4, when the driver circuit DDC is lowered further toward the display panel DSP, the terminal TN of the driver circuit DDC and the pad PD of the display panel DSP may come into contact (or direct contact) with each other. In such an embodiment, since the viscosity of the first viscous layer Na is relatively small, the first viscous layer Na between the terminal TN and the pad PD may be pushed toward the periphery of the pad PD by the pressure applied by the terminal TN. Since the viscosity of the second viscous layer Nb is relatively large, the first viscous layer Na pushed out to the periphery of the pad PD cannot spread in the left and right directions and may move onto the second viscous layer Nb. In an embodiment, for example, a second subsidiary viscous layer Na2 may be formed on the second viscous layer Nb. As a result, the first viscous layer Na may be removed between the terminal TN and the pad PD, and a part of the first viscous layer Na around the terminal TN may be located between the second viscous layer Nb and the driver circuit DDC or the substrate 300 of the driver circuit DDC to fill between them. Accordingly, the pad PD of the display panel DPS and the terminal TN of the driver circuit DDC can be reliably in contact with each other. In addition, it is possible to also suppress bubbles between the display panel DSP and the driver circuit DDC.

Subsequently, heat may be applied to the bonding layer NCF to harden (e.g., cure) the bonding layer NCF. As a result, the degree of hardening the first viscous layer Na and the second viscous layer Nb can be improved.

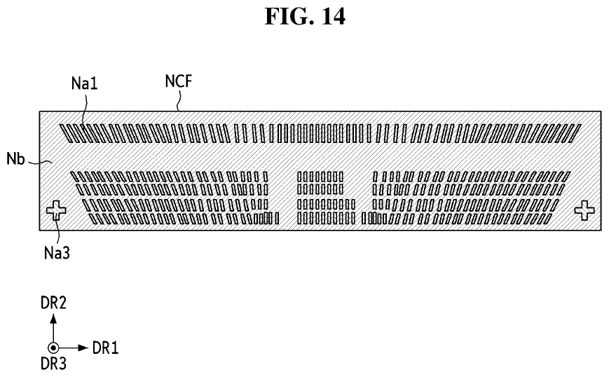

FIG. 14 is a plan view of a bonding layer NCF according to an embodiment of the present disclosure.

As shown in FIG. 14, the bonding layer NCF between the display panel DSP and the driver circuit DDC may further include a third subsidiary viscosity layer Na3 overlapping with alignment marks AM. In an embodiment, for example, the first viscous layer of the bonding layer NCF may further include the third subsidiary viscous layer Na3 overlapping the alignment marks AM in the third direction DR3. The third substrate viscous layer Na3 may overlap the alignment marks AM on the display panel DSP or the substrate SUB of the display panel DSP. The viscosity of the third subsidiary viscous layer Na3 may be equal to the viscosity of the first subsidiary viscous layer Na1 described above.

As described above with reference to FIGS. 9 to 11, in an embodiment where the bonding layer NCF further includes the third subsidiary viscous layer Na3 associated with the alignment marks AM, the driver circuit DDC and the display panel DSP can be aligned more easily in FIG. 12. In an embodiment, for example, the third subsidiary viscous layer Na3 can be easily detected due to the difference in transparency between the third subsidiary viscous layer Na3 and the second viscous layer Nb. In an embodiment where the bonding layer NCF further includes the dye described above, the third subsidiary viscous layer Na3 can be more easily detected.

The display device 100 according to an embodiment may be applied to a variety of electronic devices. An electronic device according to an embodiment includes the display device 100 described above, and may further include a module or device having additional features in addition to the display device 100.

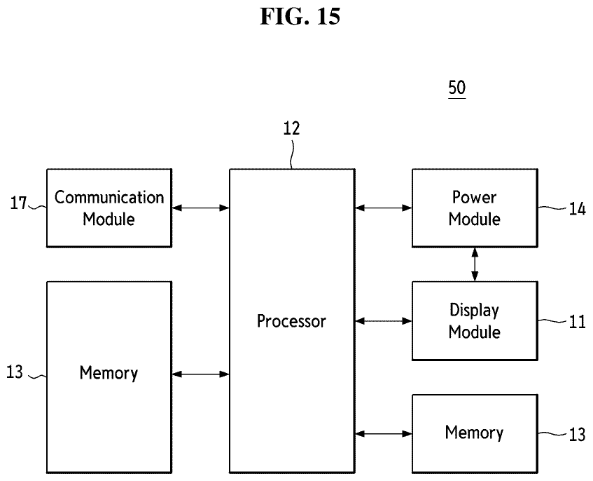

FIG. 15 is a block diagram of an electronic device according to an embodiment of the present disclosure. Referring to FIG. 15, an electronic device 50 according to an embodiment of the present disclosure may include a display module 11, a processor 12, a memory 13, and a power module 14. The electronic device 50 may further include an input module 14, a non-image output module 15, and/or a communication module 16.

The electronic device 50 may output various information in the form of images through the display module 11. When the processor 12 executes an application stored in the memory 13, image information provided by the application may be provided to the user through the display module 11. The power module 14 may include a power supply module such as a power adapter and a battery device, and a power conversion module that converts the power supplied by the power supply module to generate power used for the operation of the electronic device 50. The input module 14 may provide input information to the processor 12 and/or the display module 11. The non-image output module 15 may receive information other than images from the processor 12, such as sound, haptic and light, and provide it to the user. The communication module 16 is responsible for transmitting and receiving information between the electronic device 50 and an external device, and may include a receiving unit and a transmitting unit.

At least one of the elements of the electronic device 50 described above may be included in the display devices according to embodiments described above. In addition, some of the individual modules functioning as a single module may be included in the display device while some others may be provided separately from the display device. In an embodiment, for example, the display device may include the display module 11, and the processor 12, the memory 13 and the power module 14 may be implemented as other devices inside the electronic device 11 instead of the display device.

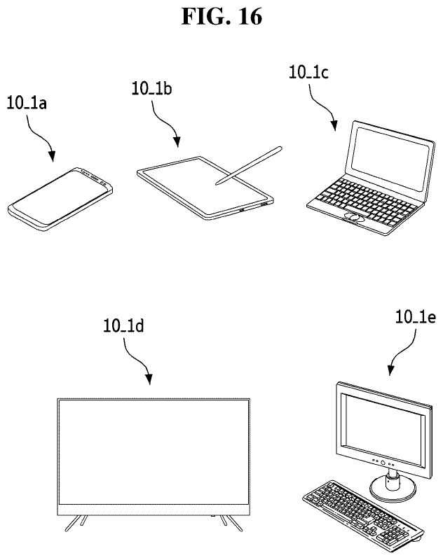

FIGS. 16, 17 and 18 are views showing electronic devices according to a variety of embodiments of the present disclosure. FIGS. 16 to 18 show examples of a variety of electronic devices employing the display devices 10 according to embodiments.

FIG. 16 shows a smartphone 10_1a, a tablet personal computer (PC) 10_1b, a laptop computer 10_1c, a television (TV) 10_1d, and a desktop monitor 10_1e as examples of the electronic devices.

The smartphone 10_1a may include an input module such as a touch sensor and a communication module in addition to a display module 11. The smartphone 10_1a may process information received through the communication module or other input modules and display the information through the display module of the display device.

The tablet PCs 10_1b, the laptop computer 10_1c, the TV 10_1d and the desktop monitor 10_1e may include display modules and input modules similar to the smartphone 10_1a, and may further include communication modules as desired.

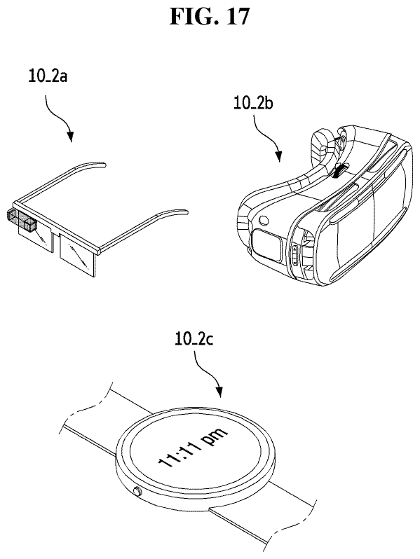

FIG. 17 shows examples of a wearable electronic device employing an electronic device including a display module. The wearable electronic devices may be smart glasses 10_2a, a head-mounted display 10_2b, a smart watch 10_2c, etc.

The smart glasses 10_2a and the head-mounted display 10_2b may include a display module that outputs display images, and a reflector that reflects the output display images and provides it to the user's eyes, thereby providing the user with images of virtual reality or augmented reality on the screen.

The smart watch 10_2c includes a biometric sensor as an input device, and may provide the user with biometric information recognized by the biometric sensor through the display module.

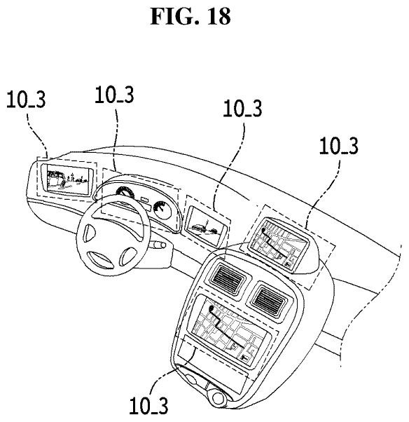

FIG. 18 shows an example of an electronic device including a display module applied to a vehicle. For example, an electronic device 10_3 may be applied to the instrument cluster, the center fascia, etc., of a vehicle, or may be applied to a center information display (CID) arranged at the dashboard of a vehicle, or may be used as a room mirror display on the behalf of the side mirrors of a vehicle.

The invention should not be construed as being limited to the embodiments set forth herein. Rather, these embodiments are provided so that this disclosure will be thorough and complete and will fully convey the concept of the invention to those skilled in the art.

While the invention has been particularly shown and described with reference to embodiments thereof, it will be understood by those of ordinary skill in the art that various changes in form and details may be made therein without departing from the spirit or scope of the invention as defined by the following claims.

What is claimed is:

1. A display device comprising:
a display panel;
a pad arranged in a non-display area of a substrate of the display panel;
a driver circuit comprising a terminal arranged on the pad; and
a bonding layer arranged between the display panel and the driver circuit in the non-display area,
wherein the bonding layer comprises:
a first viscous layer overlapping the terminal in a thickness direction of the display panel; and
a second viscous layer arranged on the display panel not to overlap the terminal in the thickness direction of the display panel, and
wherein a viscosity of the first viscous layer is different from a viscosity of the second viscous layer.

2. The display device of claim 1, wherein the viscosity of the first viscous layer is less than the viscosity of the second viscous layer.

3. The display device of claim 1, wherein the first viscous layer comprises: a first subsidiary viscous layer overlapping the terminal in the thickness direction of the display panel; and a second subsidiary viscous layer arranged between the second viscous layer and the driver circuit.

4. The display device of claim 3, wherein the first subsidiary viscous layer and the second subsidiary viscous layer are formed as a single unitary indivisible body.

5. The display device of claim 1, wherein the pad and the terminal are in contact with each other.

6. The display device of claim 5, wherein the first viscous layer is not arranged between the pad and the terminal.

7. The display device of claim 1, wherein the bonding layer comprises a dye.

8. The display device of claim 1, wherein the first viscous layer of the bonding layer further comprises a third subsidiary viscous layer overlapping an alignment mark of the display panel in the thickness direction of the display panel.

9. The display device of claim 3, wherein the first subsidiary viscous layer surrounds the terminal in a plan view.

10. The display device of claim 3, wherein an edge of the first subsidiary viscous layer surrounds the pad in a plan view.

11. The display device of claim 1, wherein the display panel further comprises a protruding pattern between the substrate of the display panel and the pad.

12. The display device of claim 11, wherein the display panel further comprises a first pad connection electrode between the substrate of the display panel and the protruding pattern.

13. The display device of claim 12, wherein the display panel further comprises a second pad connection electrode between the first pad connection electrode and the protruding pattern.

14. The display device of claim 13, wherein the display panel further comprises a third pad connection electrode between the protruding pattern and the pad.

15. An electronic device comprising:
a display device which provides a screen,
wherein the display device comprises:
a display panel;
a pad arranged in a non-display area of a substrate of the display panel;
a driver circuit comprising a terminal arranged on the pad; and
a bonding layer arranged between the display panel and the driver circuit in the non-display area,
wherein the bonding layer comprises:
a first viscous layer overlapping the terminal in a thickness direction of the display panel; and
a second viscous layer arranged on the display panel not to overlap the terminal in the thickness direction of the display panel, and
wherein a viscosity of the first viscous layer is different from a viscosity of the second viscous layer.

16. The electronic device of claim 15, wherein the viscosity of the first viscous layer is less than the viscosity of the second viscous layer.

17. The electronic device of claim 15, wherein the first viscous layer comprises:
a first subsidiary viscous layer overlapping the terminal in the thickness direction of the display panel; and
a second subsidiary viscous layer arranged between the second viscous layer and the driver circuit.

18. The electronic device of claim 15, wherein the electronic device comprises a smartphone, a tablet PC, a laptop computer, a TV, a desktop monitor, smart glasses, a smart watch, a head-mounted display, and a display for vehicles.

19. A method for fabricating a display device, the method comprising:
preparing a display panel comprising a pad in a non-display area of a substrate;
forming a bonding layer on the pad;
placing a mask above the bonding layer in a way such that a semi-transparent region of the mask overlaps the pad and a transparent region of the mask does not overlap the pad;
irradiating the bonding layer with ultraviolet ray through the mask to form the bonding layer in which a first viscous layer overlapping the semi-transparent region and a second viscous layer overlapping the transparent region have different viscosities from each other;
arranging a driver circuit on the bonding layer to overlap a terminal of the driver circuit with the first viscous layer of the bonding layer; and
lowering the driver circuit toward the bonding layer to bring the terminal of the driver circuit into contact with the pad.

20. The method of claim 19, wherein a viscosity of the first viscous layer is less than a viscosity of the second viscous layer.
